(19) United States
(12) Patent Application Publication
(10) Pub. No.: US 2025/0348007 A1
(43) Pub. Date: Nov. 13, 2025

(54) MEASURING METHOD, STORAGE MEDIUM, MEASURING DEVICE, LITHOGRAPHY APPARATUS, AND ARTICLE MANUFACTURING METHOD

(71) Applicant: CANON KABUSHIKI KAISHA, Tokyo (JP)

(72) Inventors: KAZUKI OTA, Tochigi (JP); WATARU YAMAGUCHI, Tochigi (JP)

(21) Appl. No.: 19/198,740

(22) Filed: May 5, 2025

(30) Foreign Application Priority Data
May 7, 2024 (JP) 2024-075410

(51) Int. Cl. G03F 7/00; G06T 7/00

(52) U.S. Cl. CPC G03F 7/70633; G03F 7/70666; G03F 7/706833; G03F 7/706837; G03F 7/706845; G03F 7/70716; G03F 7/70775; G06T 7/001; G06T 2207/30148

(57) ABSTRACT

A measuring method for measuring distortion of a substrate includes capturing images of a plurality of partial regions of a pattern formed in a device region of the substrate, measuring a position of the pattern based on the images acquired by the image capturing, and processing of determining a period of the pattern based on the images acquired by the image capturing, and determining distortion in the region of the substrate where the pattern is formed, based on the determined period and a measurement result acquired in the measuring.

### BACKGROUND

### Field of Technology

The present disclosure relates to a measuring method, a storage medium, a measuring device, a lithography apparatus, and an article manufacturing method.

### Description of the Related Art

In recent years, in exposure devices used for manufacturing semiconductor devices and the like, improvement of the overlay accuracy between an original plate and a substrate has been demanded, together with miniaturization of resolution line widths. Because the overlay accuracy normally needs to be approximately one-fifth of the resolution line width, improvement of the overlay accuracy becomes increasingly important along with advance of the miniaturization of semiconductor devices.

For improvement of the overlay accuracy, there is a technique that obtains the shape of a shot region by measuring positions of alignment marks arranged in a plurality of shot regions on the substrate and correcting the obtained shape (e.g., Japanese Patent Laid-Open No. 2015-038985).

However, the alignment marks are arranged in a peripheral region surrounding a device region, which should originally be corrected, of the semiconductor. Because the amount of distortion generated in the semiconductor manufacturing process differs between the device region and the peripheral region, even if the alignment marks arranged in the peripheral area are measured, it does not mean that the device area was measured accurately and correctly. To precisely and correctly measure the device region, it is necessary to directly measure the device region. As a method for directly measuring the device region of the semiconductor, there is a method in which a specific pattern in the device region is registered and the amount of positional deviation is measured using the registered pattern (e.g., Japanese Patent Laid-Open No. 2022-052530).

In a case, however, where a periodic pattern is formed in the device region of the semiconductor, an error arises due to period of the periodic pattern, which may lead to a decrease in the measurement accuracy of the periodic pattern.

### SUMMARY

The present disclosure in its one aspect provides a measuring method for measuring distortion of a substrate, including capturing images of a plurality of partial regions of a pattern formed in a device region of the substrate, measuring a position of the pattern based on the images acquired by the image capturing, and processing of determining a period of the pattern based on the images acquired by the image capturing, and determining distortion in the region of the substrate where the pattern is formed, based on the determined period and a measurement result acquired in the measuring.

Features of the present disclosure will become apparent from the following description of embodiments with reference to the attached drawings. The following description of embodiments are described by way of example.

### BRIEF DESCRIPTION OF THE DRAWINGS

FIG. 1 is a diagram illustrating the configuration of an exposure device;

FIG. 2 is a diagram exemplifying a plurality of shot regions on a substrate;

FIG. 3 is a diagram illustrating a structure example of the shot region;

FIGS. 4A and 4B are diagrams illustrating a relationship between a periodic pattern formation region and a field of view of an image capturing device in the first embodiment;

FIGS. 5A to 5C are diagrams for explaining a position measuring method based on periodic pattern images;

FIG. 6 is a diagram illustrating a relationship between a substrate stage position and measurement values of the periodic pattern;

FIG. 7 is a flowchart illustrating a distortion measuring method in the first embodiment;

FIGS. 8A and 8B are diagrams for explaining a method of measuring the period;

FIG. 9 is a graph illustrating measurement values of the periodic pattern with respect to the substrate stage position;

FIG. 10 is a graph of the measurement values of the periodic pattern after unwrapping processing;

FIG. 11 is a graph of the measurement values of the periodic pattern after uncertainty value correction;

FIG. 12 is a graph of the measurement values of the periodic pattern after removing changes, caused by driving of the substrate stage, in the measurement values;

FIG. 13 is a diagram illustrating concrete examples of measurement conditions;

FIG. 14 is a flowchart illustrating a distortion measuring method in a second embodiment.

FIG. 15 is a diagram for explaining a processing for acquiring a difference in distortion;

FIG. 16 is a diagram illustrating a relationship between a periodic pattern formation region and a field of view of an image capturing device in a third embodiment;

FIG. 17 is a flowchart illustrating a distortion measuring method in a fourth embodiment; and

FIG. 18 is a diagram illustrating an example of image capturing regions included in a measurement field of view in the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

### First Embodiment

Hereinafter, an explanation will be given as to an embodiment in which a measuring device for measuring distortion of a substrate is built in a lithography apparatus. The lithography apparatus is an apparatus that transfers a pattern onto a substrate, which may be, for example, an exposure device, an imprint device, an electron beam writing device and the like. In the following, for providing a concrete example, an explanation will be given as to an embodiment of a case where the lithography apparatus is an exposure device.

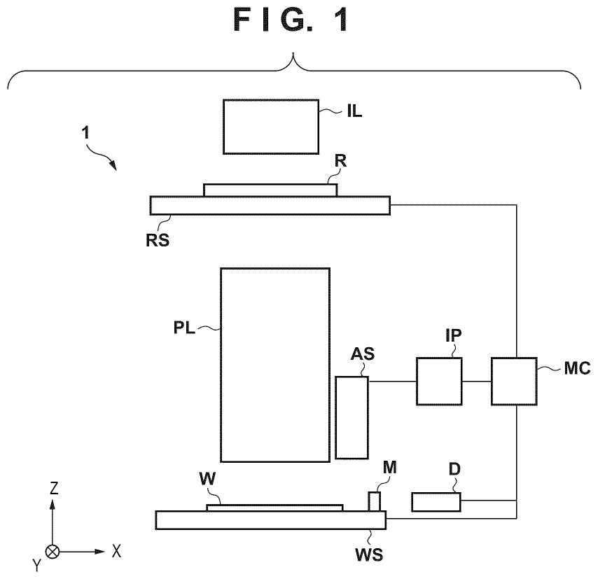

FIG. 1 is a diagram illustrating the configuration of an exposure device 1 as an example of the lithography apparatus. The exposure device 1 is a lithography apparatus that is used in a lithography process, which is part of a process of manufacturing an article or a device such as a semiconductor device or a liquid crystal display device, and that forms a pattern on a substrate W. In the specification and the accompanying drawings, directions will be indicated on an XYZ coordinate system in which a horizontal surface is defined as the X-Y plane. Generally, a substrate W, which is a substrate to be exposed, is placed on a substrate stage WS so that the surface of the substrate W becomes parallel to the horizontal surface (X-Y plane). In the following description, directions orthogonal to each other within a plane along the upper surface of the substrate stage WS on which the substrate W is placed will be defined as the X-axis and the Y-axis, and a direction perpendicular to the X-axis and the Y-axis will be defined as the Z-axis. Also, in the following description, directions parallel to the X-axis, the Y-axis, and the Z-axis in the XYZ coordinate system will be referred to as the X direction, the Y direction, and the Z direction, respectively.

The exposure device 1 may be a scanning-type exposure device (scanner). The scanning-type exposure device is a type of the exposure device that exposes a pattern formed on a mask R, which is an original plate, onto the substrate W while synchronously moving the mask R and the substrate W in a scanning direction (e.g., the Y direction). It should be noted, however, that the present invention is not limited to the scanning-type exposure device. The exposure device 1 may also be an exposure device (stepper) that exposes the pattern of the mask R onto the substrate W in a state where the mask R and the substrate W are fixed. Furthermore, the present invention can be applied not only to the exposure devices but also to an imprint batch exposure device, a substrate inspection device, and the like.

In this embodiment, the exposure device 1 is a step-and-scan type scanning exposure device that scans and exposes the substrate W with the use of slit light. The exposure device 1 may include an illumination optical system IL, a mask stage RS that holds the mask R, a projection optical system PL, the substrate stage WS that holds the substrate W, an image capturing device AS, a detector D, a controller MC, and a processor IP. The controller MC may be composed of a computer (information processor), for example, that includes a processor such as a Central Processing Unit (CPU) and a storage unit such as a memory. The controller MC controls the exposure processing of the substrate W by controlling each part of the exposure device 1 according to a program stored in the storage unit. The program may also include a program for causing the processor to execute each step of a measuring method to be described later.

The illumination optical system IL irradiates a part of the mask R with light emitted from a light source (not shown) such as an excimer laser. The mask R is held by the mask stage RS, and the substrate W is held by the substrate stage WS. The mask R and the substrate W are respectively arranged at an optically conjugate position via the projection optical system PL. The projection optical system PL has a predetermined projection magnification (e.g., ½× or ¼×) and projects the pattern formed on the mask R onto the substrate.

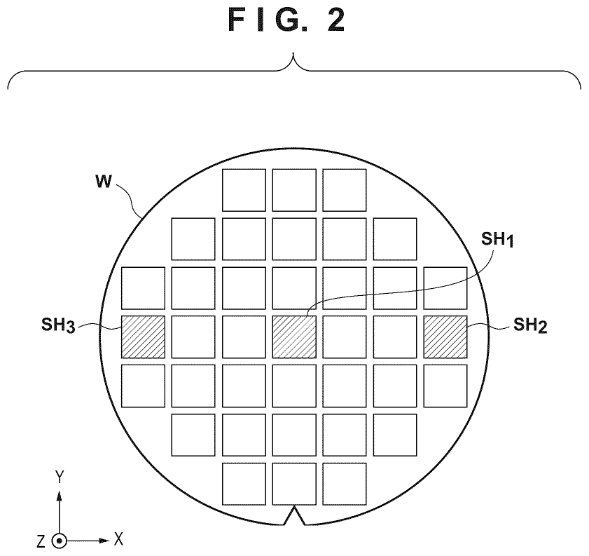

A region of the substrate W where the pattern of the mask R is projected is referred to as a shot region. In the substrate W, a plurality of shot regions including shot regions SH₁, SH₂, and SH₃ are arranged, as illustrated in FIG. 2. In the following, in a case where there is no need to specify any one of the shot regions SH₁, SH₂, or SH₃ among the plurality of shot regions, a term “shot region SH” will be used without using suffixes.

The mask stage RS and the substrate stage WS are configured to be movable in a direction perpendicular to the optical axis of the projection optical system PL, and are relatively scanned at a speed ratio corresponding to the projection magnification of the projection optical system PL, while being synchronized with each other. With this configuration, by scanning the shot region SH on the substrate, the pattern of the mask R can be transferred onto the shot region SH on the substrate. By sequentially repeating this scanning exposure for each of the plurality of shot regions on the substrate, the exposure processing on one substrate W can be completed.

The detector D includes, for example, a laser interferometer, and detects a position of the substrate stage WS. The laser interferometer included in the detector D irradiates laser light toward a reflector M provided on the substrate stage WS, and detects, by the laser light reflected on the reflector M, displacement from a reference position on the substrate stage WS. With this, the detector D can acquire a current position of the substrate stage WS based on the detected displacement. Here, although the detector D uses a laser interferometer when detecting the position of the substrate stage WS, it is not limited to this, and an encoder may be used, for example.

The substrate stage WS holds the substrate W via a substrate chuck (not shown) that chucks the substrate W. The substrate stage WS may be driven by a substrate driving mechanism (not shown). The substrate driving mechanism is a positioning mechanism for positioning the substrate W based on a result of measurement by the measuring device of this embodiment. The substrate driving mechanism includes a linear motor or the like, and by driving the substrate stage WS in the X, Y, Z directions and in a rotational direction around each axis, the substrate driving mechanism can move the substrate W held by the substrate stage WS.

The image capturing device AS may include an illumination unit (not shown). Light from the illumination unit illuminates the substrate W, and the reflected light enters the image capturing device AS. The image capturing device AS captures the incident light by an imaging device and generates an image signal. The image signal is transferred to the processor IP.

The processor IP performs a measurement processing of a mark position using a method such as a template matching method or a phase limited correlation method, based on the images acquired by the image capturing device AS. The processor IP may be a computer device that includes a CPU and memories. It should be noted that the processor IP and the controller MC may be configured as separate devices, or the function of the processor IP and the function of the controller MC may be realized by one computer device.

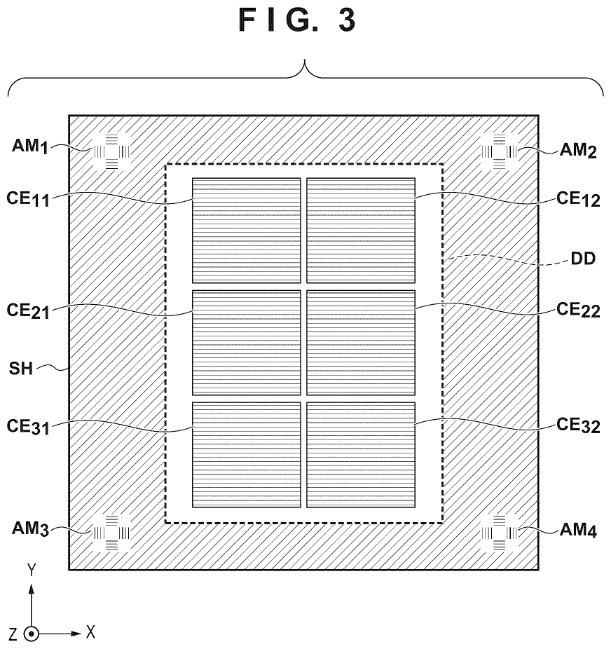

FIG. 3 is a diagram illustrating a structural example of the shot region SH. The shot region SH includes a device region DD where a device pattern is formed, and a peripheral region SL that surrounds the device region DD. In the shot region SH, a plurality of alignment marks are arranged. Generally, the plurality of alignment marks are arranged at four corners of the shot region SH. In the example of FIG. 3, alignment marks AM₁ to AM₄ are arranged at the four corners of the peripheral region SL within the shot region SH. On the other hand, in the device region DD, periodic pattern formation regions CE₁₁ to CE₃₂ are arranged. There is a difference in pattern density between the device region DD and the peripheral region SL, thus a difference arises in the way of occurrence of distortion caused by the semiconductor manufacturing process. For this reason, in the measurement of the shape of the shot region SH using the alignment marks AM₁ to AM₄, it is difficult to measure the distortion of the device region DD with high precision.

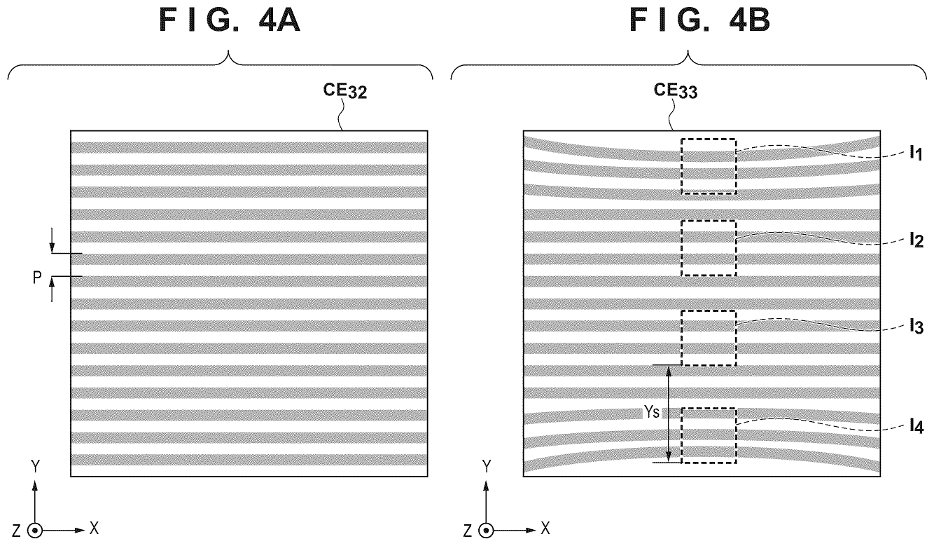

Referring to FIGS. 4A and 4B, an explanation will be given as to a relationship between the periodic pattern formation region and a measurement field of view of the image capturing device AS. FIG. 4A illustrates an ideal periodic pattern formation region CE₃₂ with no distortion. The pattern formed in the periodic pattern formation region CE₃₂ is a line-and-space periodic pattern having a periodic structure in the Y direction. The period of the line-and-space pattern is P. Although the measurement of the line-and-space periodic pattern having the periodic structure in the Y direction is described here, the disclosed technology is also applicable to a periodic pattern having the periodic structure in the X direction, or a periodic pattern having the periodic structure in both of the X direction and the Y direction. Additionally, the periodic pattern formation region CE may be understood as an already formed underlying pattern.

However, in practice, the substrate has the distortion, hence the period of the pattern is not constant at P. FIG. 4B illustrates a periodic pattern formation region CE₃₃ with distortion.

As a method for measuring the distortion of the periodic pattern, there can be considered a method in which the entire region of the periodic pattern is imaged at once and distortion distribution is acquired by calculating the period P of the periodic pattern. However, in a case where the measurement field of view of the image capturing device AS is narrow relative to the periodic pattern formation region CE, the above-mentioned method cannot be employed. Therefore, it is necessary to measure the position of the pattern based on the periodic pattern image acquired by capturing images of a plurality of partial regions of the pattern formed in the device region of the substrate. FIG. 4B illustrated an example with a plurality of measurement regions I₁, I₂, I₃, and I₄ as the plurality of partial regions. In FIG. 4B, the plurality of measurement regions I₁ to I₄ are set to be arranged in a direction parallel to the periodic direction of the pattern (Y direction) with a predetermined pitch (a relative driving amount Ys between the image capturing device AS and the periodic pattern formation region CE).

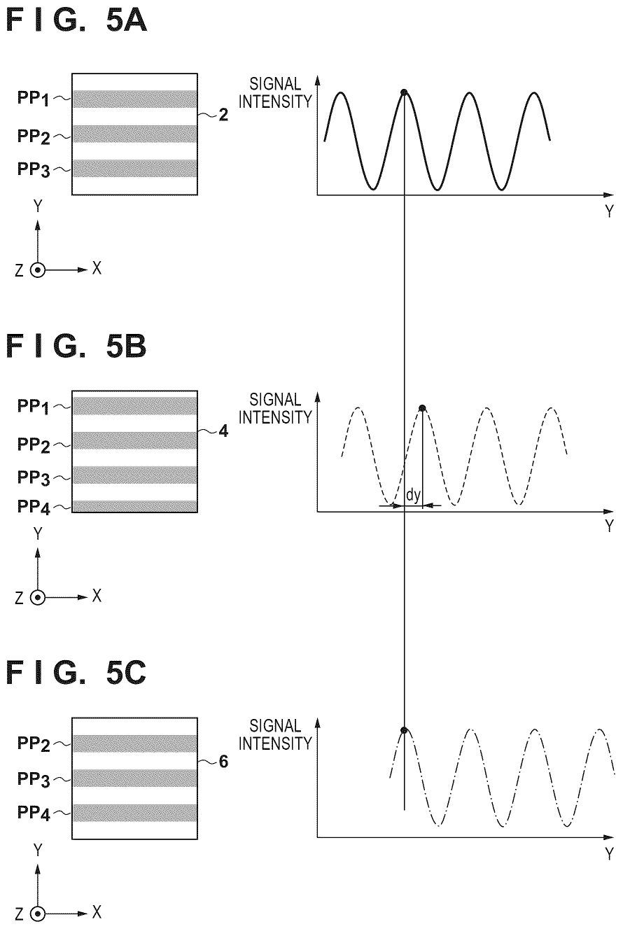

Referring to FIGS. 5A to 5C, an explanation will be given as to a position measuring method based on periodic pattern images. FIGS. 5A to 5C illustrate an example of the position measurement of a line-and-space periodic pattern using the template matching. FIG. 5A illustrates a template image 2 with a periodic pattern and a signal intensity waveform 3 acquired by the image capturing device AS. FIG. 5B illustrates an acquired image 4 and a signal intensity waveform 5 in a case where a relative position between the image capturing device AS and the periodic pattern formation region CE is shifted by dy. By collating the template image 2 (signal intensity waveform 3) and the acquired image 4 (signal intensity waveform 5) by the position measurement of the periodic pattern, the deviation amount dy (phase difference) from the template can be determined as the measurement value. FIG. 5C illustrates an acquired image 6 and a signal intensity waveform 7 in a case where a relative position between the image capturing device AS and the periodic pattern formation region CE is shifted by P which corresponds to one cycle of the periodic pattern. In a case where the relative position change between the image capturing device AS and the periodic pattern formation region CE is an integer multiple of P, the acquired image 6 (signal intensity waveform 7) and the template image 2 (signal intensity waveform 3) become the same image with a pitch shift.

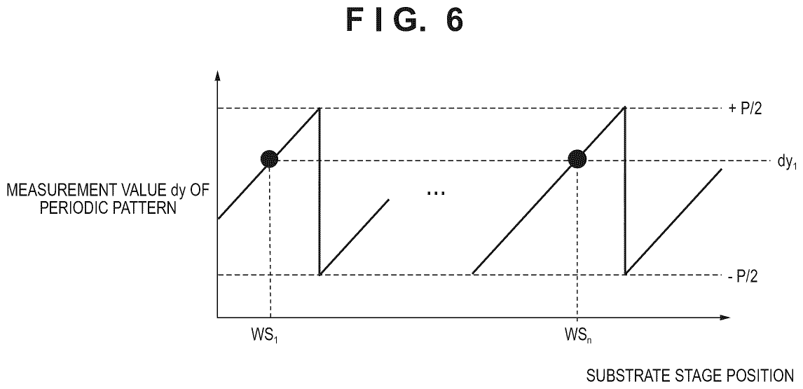

FIG. 6 is a diagram illustrating a relationship between a relative position of the image capturing device AS and the periodic pattern formation region CE, and the measurement value of the periodic pattern. In FIG. 6, the substrate stage position is taken on the abscissa, as representing the relative position between the image capturing device AS and the periodic pattern formation region CE. The ordinate represents the measurement value dy of the periodic pattern. As illustrated in FIG. 6, the measurement value dy is folded within the range of ±P/2. Therefore, at the substrate stage position WSₙ (n is an integer greater than or equal to 1), the measurement value becomes dy₁+n×P, hence an integer multiple uncertainty value (=n×P) occurs. This uncertainty value can be distortion measurement error of the periodic pattern formation region.

Therefore, in this embodiment, based on the information about the position of the substrate stage WS acquired by the detector D and the period P determined from the captured periodic pattern image, multiple position measurement results of the periodic pattern are corrected. By correcting the uncertainty value, the distortion within the periodic pattern formation region can be measured with high precision.

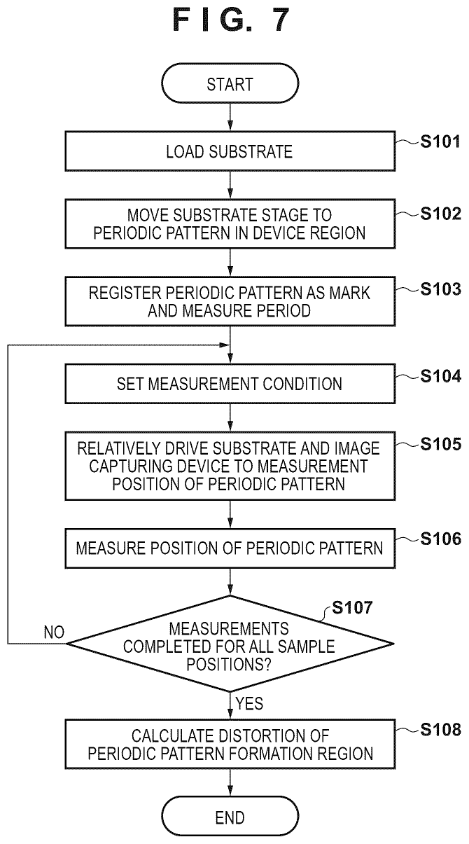

FIG. 7 is a flowchart illustrating the distortion measurement processing within the periodic pattern formation region.

In S101, the controller MC causes the substrate W, which is the processing target, to be loaded into the exposure device 1 from a substrate transfer device (not shown) (substrate loading). The substrate W is placed and held on the substrate stage WS.

In S102, the controller MC adjusts the relative position between the substrate W and the image capturing device AS by the substrate stage WS in order to capture images of the periodic pattern of the measuring target (substrate transfer).

In S103, the processor IP registers the periodic pattern images of the periodic pattern formation region CE as marks and measures the period P based on the periodic pattern images. Note that by performing in advance registration of the periodic pattern images and measurement of the period P of the periodic pattern, S103 can be omitted.

In S104, the controller MC sets a measurement condition. The measurement conditions may include the shot region SH on the substrate W to be measured, the periodic pattern formation region CE, the number of measurement regions within the periodic pattern formation region (the number of multiple sub-regions), a relative driving amount Ys between the image capturing device AS and the periodic pattern formation region CE, and so on. FIG. 4B illustrates a case where the shot region SH₁, the periodic pattern formation region CE₃₃, the measurement regions I₁ to I₄, and the relative driving amount Ys are set as the measurement conditions. Here, the regions to be captured by the image capturing device AS are the measurement region I₁ to I₄.

In S105, in order to capture the measurement regions Ito I₄, the controller MC adjusts the relative position between the substrate W and the image capturing device AS by the substrate stage WS (adjusting step). Thereafter, one sub-region (e.g., the measurement region I₁) is imaged by the image capturing device AS. (image capturing step)

In S106, the processor IP performs the position measurement of the periodic pattern based on the periodic pattern images acquired by image capturing by the image capturing device AS (measuring step). This measuring step is a step of outputting, as measurement values, phase differences of signal intensity waveforms acquired from respective images of the multiple sub-regions.

In S107, the controller MC determines whether or not the position measurements for all of the measurement regions (sample positions) on the substrate W, which are set in S104, have been completed. In a case where there are unmeasured measurement regions (NO in S107), the process returns to S104. By this procedure, the adjusting step, the image capturing step, and the measuring step are performed for each of the multiple sub-regions. In a case where the measurements have been completed for all of the measurement regions on the substrate W (YES in S107), the process moves to S108.

In S108, the controller MC calculates the distortion of the periodic pattern formation region. S108 is a processing step of determining the period of pattern based on the images acquired in the image capturing step, and determining the distortion (distortion amount) of the periodic pattern formation region on the substrate W based on the determined period and the measurement results acquired in the measuring step.

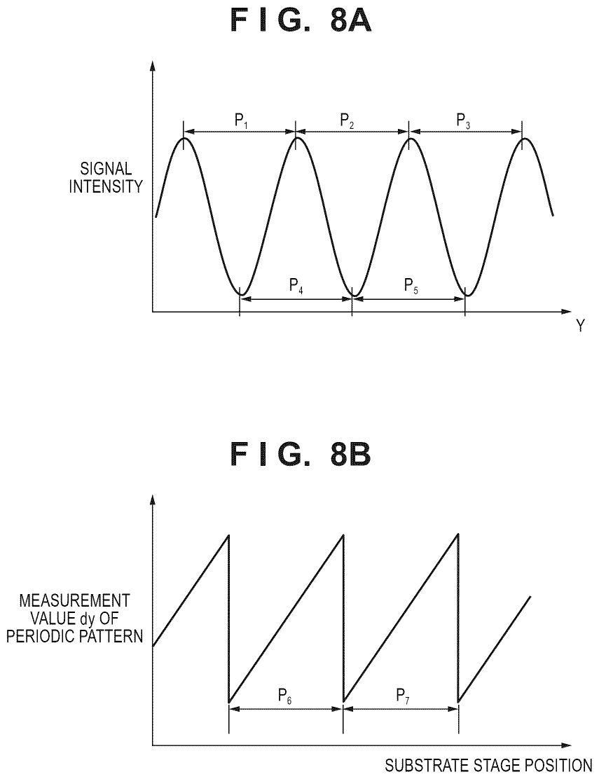

FIG. 8A illustrates a signal intensity waveform of the periodic pattern image acquired by image capturing by the image capturing device AS. The abscissa represents the position in the Y direction. In the processing step, the period of the pattern is determined based on the signal intensity waveform acquired from the periodic pattern image. For example, because the periodic pattern image contains one or more periods, multiple periods (e.g., P₁ to P₅) may be determined from the signal intensity, and an average value of these periods may be used as the period P of the periodic pattern. Furthermore, the period may be determined after differentiating the signal intensity of the periodic pattern image. Alternatively, in the processing step, the period of the pattern may be determined based on the relationship between the position of the substrate stage WS acquired by the detection by the detector D and the measurement value dy. FIG. 8B illustrates the measurement value dy of the periodic pattern with respect to the substrate stage position. Because the measurement value is folded within a range of the periodic pattern period P, the periodic pattern periods P₆ and P₇ can be determined from the position information of the substrate stage WS acquired by the detector D. Similarly to the above, the periods may be determined in multiple regions, and an average value of these periods may be used as the period P of the periodic pattern.

In the processing step, based on the determined period and the position information of the substrate stage WS at the time of capturing the image of each of the plurality of partial regions in the image capturing step, the measurement results obtained in the measuring step are corrected, and based on the corrected measurement results, the distortion of the pattern formation region can be determined. The position information of the substrate stage WS is the position information of the substrate stage WS obtained from the detector D each time the relative position is adjusted in the adjusting step. Hereinafter, a concrete example of the processing for determining the distortion of the pattern formation region will be shown.

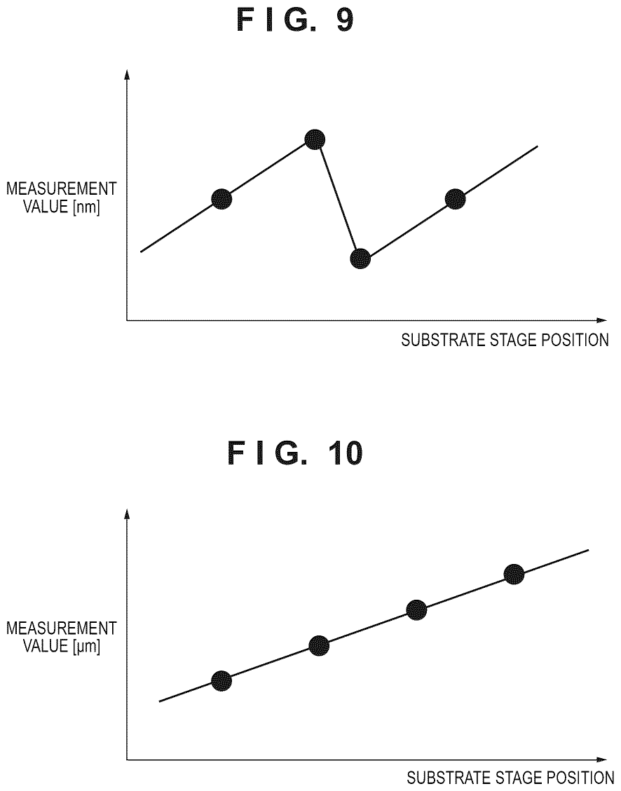

FIG. 9 is a graph illustrating measurement values of the periodic pattern at multiple positions of the substrate stage acquired in the processing of S104 to S107. This graph shows the relationship between the position information of the substrate stage WS acquired by the detector D, and the measurement value. As described above, the measurement value of this periodic pattern is folded (wrapped) within the range of ±P/2. Therefore, discontinuity points (wrap point, cusp point, singular point) of the measurement value, which are caused by the wrapping of the measurement value, are being occurred. Here, the occurrence of discontinuity points of the measurement value may also include a case where a slope in the relationship (graph) between the position information and the measurement values becomes discontinuous. Also, it may include a case where the measurement value is not differentiable at the discontinuity points. Therefore, the processing step (S108) may include unwrapping processing, for the measurement results shown in FIG. 9, that makes the discontinuous points of the measurement value continuous using the period P determined in S103.

FIG. 10 illustrates the measurement value of the periodic pattern after performing the unwrapping processing to the measurement value of the periodic pattern illustrated in FIG. 9. Since components of the uncertainty value n x P are included in the measurement value of the periodic pattern each time relative driving is carried out, it is necessary to correct the uncertainty value using the position information of the substrate stage WS acquired by the detector D and the period P. In the embodiment, the value of n can be specified from the position information of the substrate stage WS acquired by the detector D. Therefore, the processing step (S108) may further include a step of correcting the measurement value subjected to the unwrapping processing based on the position information of the substrate stage WS acquired by the detector D and the determined period P.

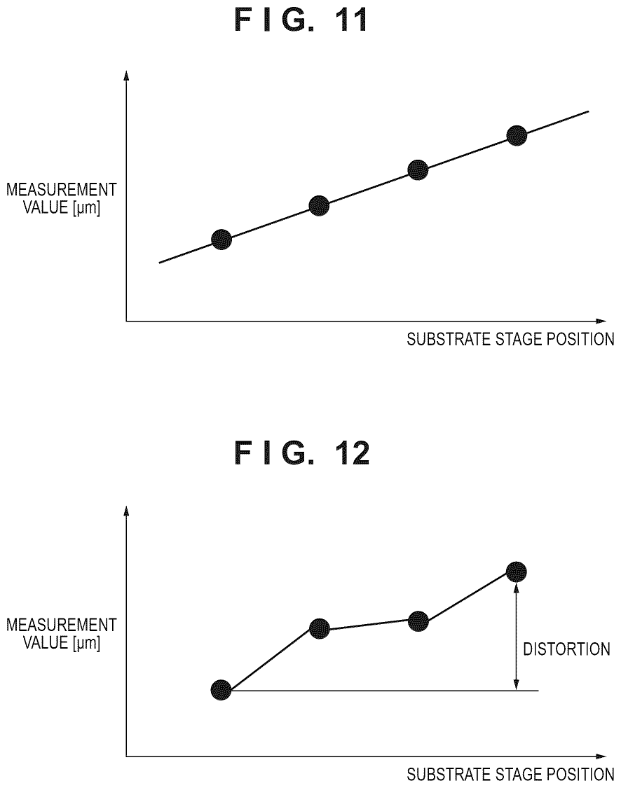

FIG. 11 illustrates the measurement values of the periodic pattern after correcting the uncertainty value. Here, the correction of the uncertainty value can be performed only in a case where the condition “the distortion of the periodic pattern generated between the relative driving amounts Ys is smaller than the period P/2” is satisfied. Therefore, the relative driving amount Ys set in S104 may be set based on distortion distribution previously acquired from the substrates W manufactured in the same process, or based on a tendency of results of the measurements of two or more points. Additionally, the relative driving amount may not be constant and may be set to a driving amount that varies according to the distortion distribution.

The processing step (S108) may further include a step of removing, with the use of the position information of the substrate stage WS acquired by the detection by the detector D, changes in the measurement values caused by the driving of the substrate stage WS from the above-mentioned measurement values subjected to the unwrapping processing and the correction. By this step, it is possible to determine the distortion of the periodic pattern formation region. FIG. 12 illustrates a result of removing, from the measurement result illustrated in FIG. 11, with the use of the position information of the substrate stage WS acquired by the detector D, the change in the measurement value caused by the driving of the substrate stage WS. The amount of change in the measurement value illustrated in FIG. 12 corresponds to the distortion in the periodic pattern formation region.

As described above, in this embodiment, the position of the periodic pattern is measured based on the periodic pattern images captured at multiple positions within the periodic pattern formation region. By correcting the measurement result, based on the position information of the substrate stage WS acquired by the detector D and the period P determined from the captured periodic pattern images, it is possible to measure the distortion in the periodic pattern formation region.

At the time of performing the exposure processing, it becomes possible to correct, based on the measured distortion, the pattern image of the mask M so that the overlay error between the underlying pattern of the substrate W and the pattern image of the mask M falls within an acceptable range.

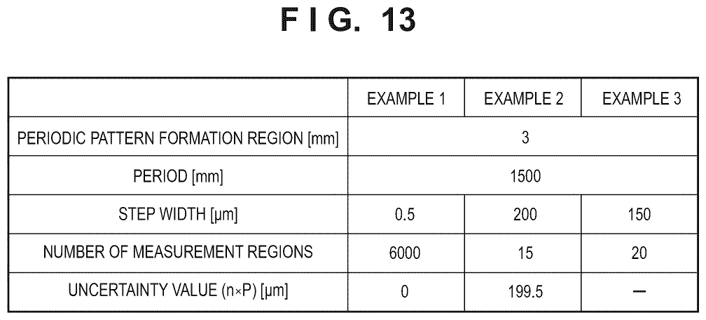

Referring to FIG. 13, an explanation will be given, by providing three examples, as to the setting of measurement conditions shown in S104.

### Example 1

As Example 1, a condition with a step width of 0.5 μm (P/2 or less) is shown. In FIG. 13, assuming that the dimension of the periodic pattern formation region CE in the measurement direction is 3 mm and the period P of the periodic pattern is 1,500 nm, the step width Ys, the number of measurement regions, and the uncertainty value n×P generated in one relative driving are shown. The number of measurement regions for measuring the entire periodic pattern formation region CE is 6,000, and the uncertainty value generated in one relative driving is 0. Therefore, by performing the unwrapping processing on the measurement results and removing the measurement value changes due to the substrate stage WS driving, it is possible to measure the distortion. Correction becomes easier, however, the number of measurement regions becomes huge, and one measurement time becomes longer.

### Example 2

As Example 2, a condition with a step width of 200 μm (P/2 or less) is shown. The number of measurement regions for measuring the entire periodic pattern formation region CE is 15, and the uncertainty value generated in one relative driving is 199.8 μm. Therefore, by performing the unwrapping processing on the measurement results, correcting the uncertainty value, and removing the measurement value changes due to the substrate stage WS driving, it is possible to measure the distortion. As such, by correcting the measurement value using a wide step width, the distortion measurement time is shortened.

### Example 3

As Example 3, a condition with a step width of 150 μm (an integer multiple of P/2) is shown. The number of measurement regions for measuring the entire periodic pattern formation region CE is 20. Here, because the step width is an integer multiple of P/2, the relative position shift of the periodic pattern due to the substrate stage WS driving is not generated. Therefore, under these conditions, it is possible to measure the distortion by performing only the unwrapping processing of the measurement results.

### Second Embodiment

An explanation will be given as to a second embodiment. As for the configuration and others of an exposure apparatus according to the second embodiment, except for the matters mentioned below, it may follow the first embodiment.

In the first embodiment, the measurement results of the periodic pattern formation region were corrected using the substrate stage position and the periodic pattern period P, and the distortion was measured. In contrast, in the second embodiment, a measurement processing including an image capturing step, a measuring step, and a processing step is performed for each of the plurality of shot regions of the substrate W, to determine the difference in distortion relative to the reference shot region.

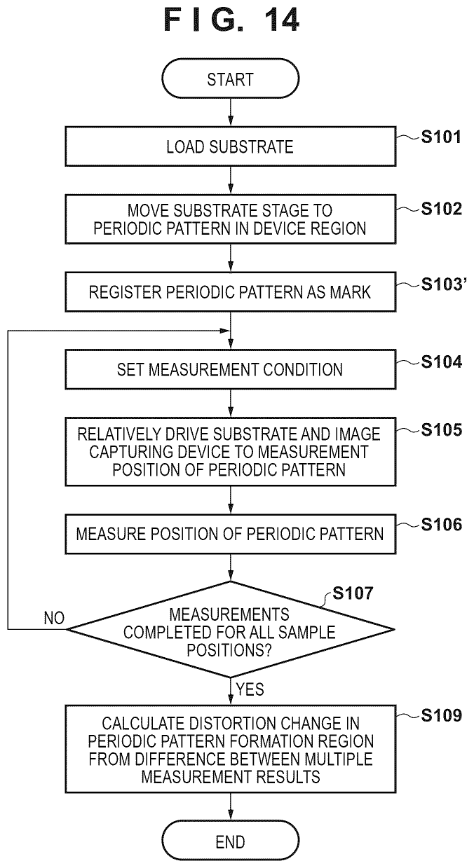

FIG. 14 is a flowchart illustrating the method for measuring the difference in distortion of the periodic pattern formation region. Here, the measurement of the periodic pattern period P in S103, which was performed in the first embodiment, is not required.

In S104, the controller MC selects measurement conditions. Here, as an example, a case is considered where three shot regions SH₁, SH₂, and SH₃, illustrated in FIG. 2, are selected.

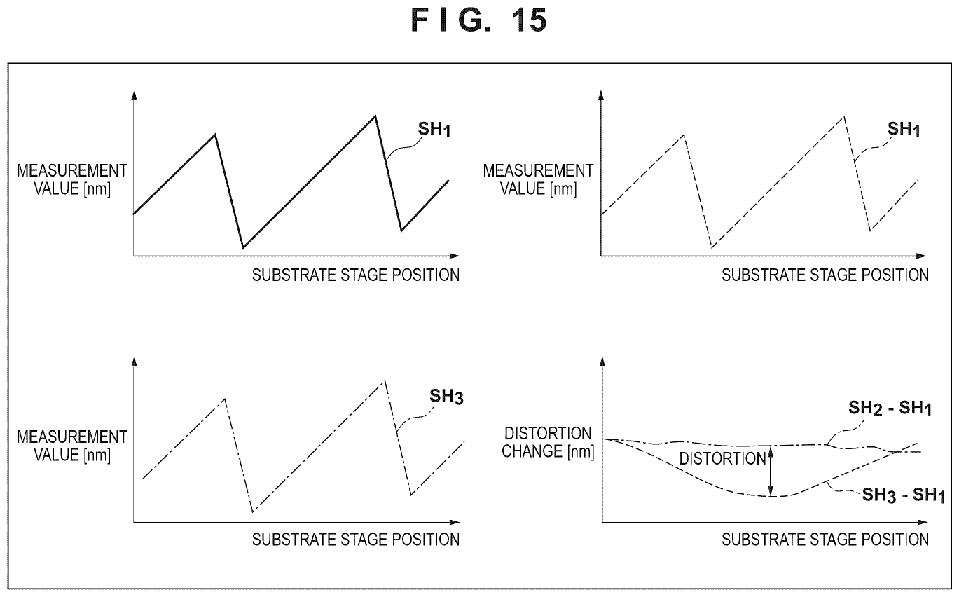

In S109, the controller MC calculates a distortion change in the periodic pattern formation region. FIG. 15 illustrates measurement results of the three shot regions SH₁ to SH₃, as well as changes in the measurement values of the shot regions SH₂ and SH₃ when taking the shot region SH₁ as a reference. Because the measurement conditions in the three shot regions SH₁ to SH₃ are the same, even with the folded measurement results, it is possible to acquire the distortion difference.

Here, the measurement values in the periodic pattern formation region of the reference shot region may be measurement values previously acquired from the substrate W manufactured in the same process. Additionally, the distortion in the periodic pattern formation region of the reference shot region may be values previously inspected by other inspection devices. Furthermore, this embodiment may be applied to a process monitor that judges something to be an abnormality in a case where the distortion change from the reference shot region exceeds a predetermined threshold value. With such a process monitor, it is possible to detect, for example, distortion in the substrate W caused by well-known semiconductor manufacturing processes (oxidation, film formation, deposition, doping, planarization, etching, resist removal, dicing, bonding, packaging, and so on), and judge the abnormality.

According to this embodiment, it is possible to measure the difference in distortion of the periodic pattern formation region from multiple measurement results acquired in different regions.

### Third Embodiment

An explanation will be given as to a third embodiment. As to the configuration and others of an exposure apparatus according to the third embodiment, except for the matters mentioned below, it may follow the first embodiment.

In the first embodiment, the plurality of measurement regions I₁ to I₄, as the plurality of partial regions, were arranged in a direction parallel to the periodic direction (Y-direction) of the periodic pattern. Therefore, the relative driving direction between the image capturing device AS and the periodic pattern formation region CE was in the periodic direction of the periodic pattern. For this reason, the measurement value was folded within the range of ±P/2, thus an uncertainty value was occurred and the measurement accuracy was lowered. In contrast, in the third embodiment, the plurality of measurement regions as plural partial regions are set to be arranged in a direction intersecting the periodic direction of the periodic pattern. That is, the relative driving direction between the image capturing device AS and the periodic pattern formation region CE is set in a non-periodic direction (e.g., X-direction) that intersects the periodic direction of the periodic pattern. For this reason, folding of the measurement values and uncertainty value do not occur, and the measurement result directly becomes the distortion amount in the periodic pattern formation region.

The procedure of distortion change measurement in the periodic pattern formation region in this embodiment is similar to the first embodiment (FIG. 7). However, the measurement of the period P of the periodic pattern in S103, which was performed in the first embodiment, is not required.

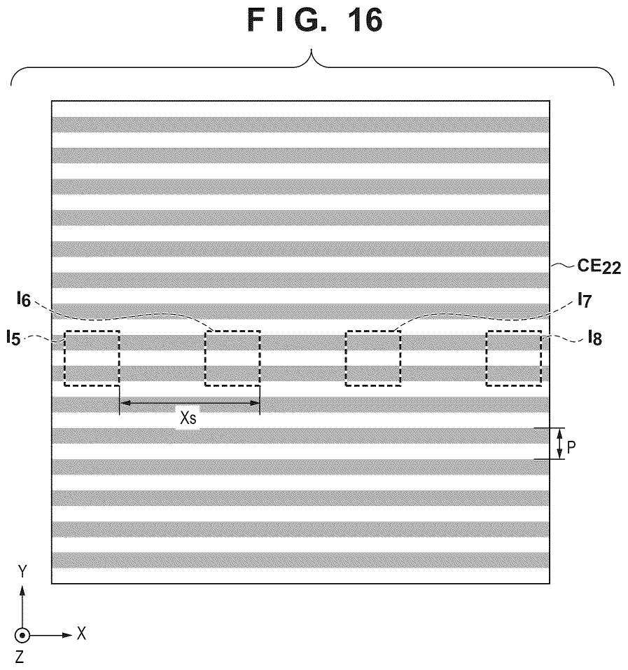

In S104, the controller MC sets the measurement conditions. FIG. 16 illustrates a concrete setting example in the third embodiment. In this example, the shot region SH₁ and the periodic pattern formation region CE₂₂ are selected, the number of measurement regions is set to 4, and the relative driving amount Xs is set. With these settings, the measurement is performed for the plurality of measurement regions I₅ to I₈. In a case of measuring the distortion in the non-periodic direction, shift in the periodic pattern due to the substrate stage WS driving does not occur.

According to this embodiment, by measuring the position based on periodic pattern images captured at multiple locations within the periodic pattern formation region, it is possible to measure the distortion in the non-periodic direction within the periodic pattern formation region.

### Fourth Embodiment

An explanation will be given as to a fourth embodiment. As to the configuration and others of an exposure apparatus according to the fourth embodiment, except for the matters mentioned below, it may follow the first embodiment.

In the first embodiment, because the alignment is not made with sufficient accuracy, the uncertainty value may occur in the measurement of the region I₁ which is to be measured first. For this reason, the change in the measurement values was measured as the distortion taking the measurement region I₁ as the reference. In contrast, in the fourth embodiment, before starting the measurement of the distortion in the substrate W, relative alignment between the image capturing device AS and the substrate W is performed based on alignment marks formed around the device region DD. By this preliminary alignment, it is possible to measure the measurement region I₁ as an absolute position.

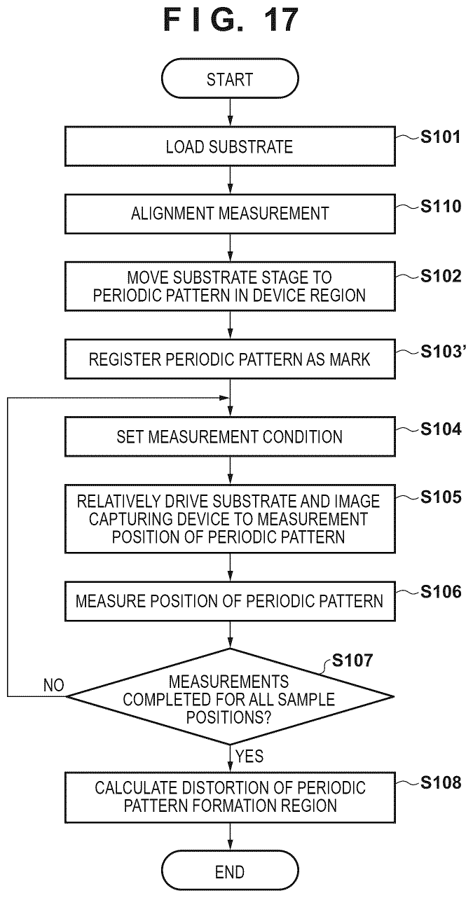

FIG. 17 is a flowchart illustrating the distortion change measurement in the fourth embodiment. In FIG. 17, S110 is added between the substrate loading in S101 and the substrate conveyance in S102. In S110, the controller MC performs an alignment measurement. For example, the controller MC adjusts the relative position between the substrate W and the image capturing device AS by the substrate stage WS so that the alignment marks AM arranged in a surrounding region SL can be measured, and thereafter, image capturing of the alignment mark AM is performed by the image capturing device AS.

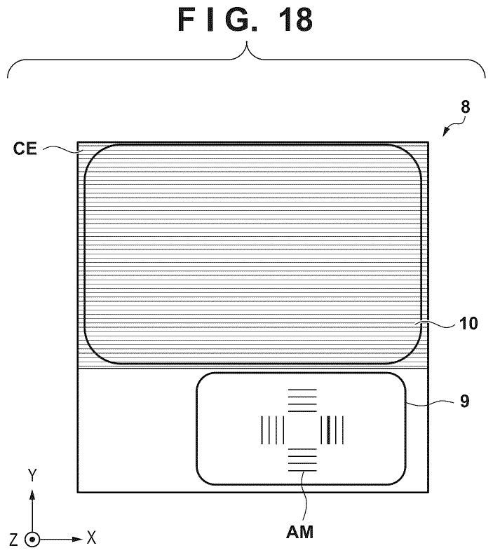

As an example of the alignment measurement, FIG. 18 illustrates an image, captured in the same field of view, of the periodic pattern formation region of the device region and the alignment marks AM arranged in the surrounding region SL. Here, the alignment mark AM may be any circuit pattern around the device. In a measurement field 8, an image capturing region 9 including the alignment marks AM arranged in the surrounding region SL and an image capturing region 10 including the periodic pattern, are included. The processor IP uses the image capturing region 9 of the measurement field 8 for alignment measurement and uses the image capturing region 10 of the measurement field 8 for position measurement of the periodic pattern.

According to this embodiment, by aligning using the alignment marks and measuring positions based on periodic pattern images captured at multiple positions within the periodic pattern formation region, it is possible to measure the distortion at an absolute position within the periodic pattern formation region.

### Embodiment of Article Manufacturing Method

An explanation will be given as to an article manufacturing method for manufacturing an article using the above-mentioned lithography apparatus. The article manufacturing method is suitable for manufacturing articles such as devices (semiconductor elements, magnetic storage media, liquid crystal display elements, and so on), for example. The manufacturing method includes a step of exposing (forming a pattern on the substrate) a substrate coated with a photosensitive material using the exposure apparatus EXA, and a step of developing the exposed substrate (processing the substrate). Additionally, the manufacturing method may include other well-known processes (oxidation, film formation, deposition, doping, planarization, etching, resist removal, dicing, bonding, packaging, and so on). The article manufacturing method in this embodiment is advantageous in at least one of the performance, quality, productivity, and production cost of the article compared to the conventional method. The above-mentioned article manufacturing method may also be carried out using lithography apparatuses such as an imprint device or a drawing device.

### Other Embodiments

Embodiment(s) of the present disclosure can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-075410, filed May 7, 2024, which is hereby incorporated by reference herein in its entirety.

What is claimed is:

1. A measuring method for measuring distortion of a substrate, comprising:
capturing images of a plurality of partial regions of a pattern formed in a device region of the substrate;
measuring a position of the pattern based on the images acquired by the image capturing; and
processing of determining a period of the pattern based on the images acquired by the image capturing, and determining distortion in the region of the substrate where the pattern is formed, based on the determined period and a measurement result acquired in the measuring.

2. The method according to claim 1, further comprising adjusting a relative position between an image capturing device used in the capturing and the substrate, wherein,
in the capturing, after the adjusting, an image of one partial region is captured,
in the measuring, the position of the pattern is measured based on the image of the one partial region, and
for each of the plurality of partial regions, the adjusting, the capturing, and the measuring are performed.

3. The method according to claim 2, wherein in the determining the period, based on information of a position of a stage that holds the substrate when capturing, in the capturing, an image of each of the plurality of partial regions and the determined period, the measurement result acquired by the measuring is corrected, and based on the corrected measurement result, the distortion in the region of the substrate where the pattern is formed is determined.

4. The method according to claim 3, wherein the information of the position of the stage is position information of the stage acquired from a detector that detects the position of the stage each time the relative position is adjusted in the adjusting.

5. The method according to claim 1, wherein in the determining the period, the period of the pattern is determined based on a signal intensity waveform acquired from the image.

6. The method according to claim 4, wherein in the measuring, a phase difference of a signal intensity waveform acquired from each image of the plurality of partial regions is output as a measurement value.

7. The method according to claim 6, wherein in the determining the period, the period of the pattern is determined based on a relationship between the position of the stage acquired by detection by the detector and the measurement value.

8. The method according to claim 7, wherein the determining the period comprises:
performing unwrapping processing to make discontinuity points of the measurement value continuous in the relationship;
correcting, based on information of the position of the stage acquired by the detection by the detector and the determined period, the measurement value subjected to the unwrapping processing; and
determining the distortion in the region where the pattern is formed, by removing, from the corrected measurement value, a change in the measurement value due to driving of the stage, using the information of the position of the stage acquired by the detection by the detector.

9. The method according to claim 1, wherein the plurality of partial regions are arranged in a direction parallel to a periodic direction of the pattern.

10. The method according to claim 1, wherein a measurement processing, which includes the capturing, the measuring, and the determining the period, is performed for each of multiple shot regions of the substrate, and a difference in distortion relative to a reference shot region is determined.

11. The method according to claim 1, wherein the plurality of partial regions are arranged in a direction intersecting a periodic direction of the pattern.

12. The method according to claim 1, further comprising performing, before starting the measurement of the distortion of the substrate, relative alignment between an image capturing device and the substrate based on a mark formed around the device region.

13. A computer-readable storage medium storing a program for causing a computer to execute a measuring method for measuring distortion of a substrate, the program causing the computer to perform:
capturing of images of a plurality of partial regions of a pattern formed in a device region of the substrate;
measuring of a position of the pattern based on the captured images, and
determining a period of the pattern based on the captured images, and determining distortion of the region of the substrate where the pattern is formed, based on the determined period and a measurement result acquired in the measuring.

14. A measuring device comprising an image capturing device and a controller, for measuring distortion of a substrate, wherein the controller is configured to:
control the image capturing device so as to
capture images of a plurality of partial regions of a pattern formed in a device region of a substrate;
measure a position of the pattern based on the images acquired by the image capturing; and
determine a period of the pattern based on the images acquired by the image capturing, and based on the determined period and a measurement result, determine distortion of a region of the substrate where the pattern is formed.

15. A lithography apparatus comprising:
a measuring device defined in claim 14, configured to measure distortion of a substrate; and
a positioning mechanism configured to position the substrate based on the distortion of the substrate measured using the measuring device,
wherein the lithography apparatus is configured to transfer a pattern onto the substrate.

16. An article manufacturing method, comprising:
transferring a pattern onto a substrate using the lithography apparatus defined in claim 15; and
acquiring an article by processing the substrate having the pattern transferred thereon.
